(19) United States
(12) Patent Application Publication
(10) Pub. No.: US 2014/0320195 A1
(43) Pub. Date: Oct. 30, 2014

(54) UNIVERSAL CONTACT INPUT APPARATUS AND METHOD FOR OPERATING THE SAME

(71) Applicant: GE INTELLIGENT PLATFORMS, INC., Charlottesville, VA (US)

(72) Inventors: Ravindra Mahavir Desai, Hyderabad (IN); Parag Vishwanath Acharya, Hyderabad (IN)

(73) Assignee: GE Intelligent Platforms, Inc., Charlottesville, VA (US)

(21) Appl. No.: 13/872,496

(22) Filed: Apr. 29, 2013

(51) Int. Cl. H03K 3/012

(52) U.S. Cl. CPC H03K 3/012
USPC 327/382

(57) ABSTRACT

At a contact input circuit, a voltage at a switching device is sensed and the voltage is associated with a status of a switching device. The contact input circuit is operated according to the sensed voltage regardless of the value of the sensed voltage. The power usage of the contact input circuit is maintained to be within a predetermined range of power consumption values regardless of the value of the sensed voltage. Wetting voltages can be continuously monitored and the approaches described herein can monitor open contact, closed contact, and open field wire conditions.

### CROSS REFERENCE TO RELATED APPLICATION

Utility application entitled “Loop Powered Isolated Universal Contact Input Circuit and Method for Operating the Same” naming as inventors Parag Acharya and Ravindra Desai, and having attorney docket number 268492 (130842) is being filed on the same date as the present application, the content of which is incorporated herein by reference in its entirety.

### BACKGROUND OF THE INVENTION

1. Field of the Invention

The subject matter disclosed herein relates to sensing information associated with switching devices and, more specifically, to sensing this information according to a wide range of operating conditions.

2. Brief Description of the Related Art

Different types of switching devices (e.g., electrical contacts, switches, and so forth) are used in various environments. For example, a power generation plant uses a large number of electrical contacts (e.g., switches and relays). The electrical contacts in a power generation plant can be used to control a wide variety of equipment such as motors, pumps, solenoids and lights. A control system needs to monitor the electrical contacts within the power plant to determine their status in order to ensure that certain functions associated with the process are being performed. In particular, the control system determines whether the electrical contacts are on or off, or whether there is a fault near the contacts such as open field wires or shorted field wires that affect the ability of the contacts to perform their intended function.

One approach that a control system uses to monitor the status of the electrical contacts is to send an electrical voltage (e.g., a direct current voltage (DC) or an alternating current (AC) voltage) to the contacts in the field and determine whether this voltage can be detected. The voltage, which is provided to the electrical contacts for detection, is known as a wetting voltage. If the wetting voltage levels are high, galvanic isolation in the circuits is used as a safety measure while detecting the existence of voltage. Detecting the voltage is an indication that the electrical contact is on or off. A wetting current is associated with the wetting voltage.

Various problems have existed with previous devices. For example, the contacts need to be isolated from the control system, or damage to the control system may occur. Also, the control system may need to handle a wide variety of different voltages, but previous devices only handle voltages within a narrow range. Previous devices have also been inflexible in the sense that they cannot be easily changed or modified over time to account for changes in the operating environment. All of these problems have resulted in general dissatisfaction with previous approaches.

### BRIEF DESCRIPTION OF THE INVENTION

A universal contact input circuit is provided that can operate across the entire wetting voltage range that is provided. In one aspect (and to enhance efficiency), the circuit automatically adjusts its impedance with wetting voltage in an attempt to keep the circuit power dissipation almost constant throughout the wetting voltage range. In still other aspects, the circuit can detect the contact status (e.g., open or closed), and are also capable of monitoring the wetting voltage.

In many of these embodiments and at a contact input circuit, a voltage at a switching device is sensed and the voltage is associated with a status of a switching device. The contact input circuit is operated according to the sensed voltage regardless of the value of the sensed voltage. The power usage of the contact input circuit is maintained to be within a predetermined range of power consumption values regardless of the value of the sensed voltage.

In some aspects, the wetting voltage of the switching device is monitored. In other aspects, a range of voltage values is determined by the monitoring. In still other aspects, the monitoring is performed continuously.

In some examples, the operation converts the sensed voltage to a useable voltage regardless of the value and type of the sensed voltage. The type of sensed voltage may be a direct current (DC) voltage or an alternating current (AC) voltage. In other examples, the status of the switching device may be an open status or a closed status.

In others of these embodiments, a contact input circuit includes a fixed attenuator sensing circuit and a control circuit. The fixed attenuator sensing circuit is configured to sense a voltage at a switching device and the voltage is associated with a status of a switching device. The control circuit is coupled to the fixed attenuator sensing circuit. The control circuit is configured to operate the contact input circuit according to the sensed voltage regardless of the value of the sensed voltage and maintain the power usage of the contact input circuit to be within a predetermined range of power consumption values regardless of the value of the sensed voltage.

### BRIEF DESCRIPTION OF THE DRAWINGS

For a more complete understanding of the disclosure, reference should be made to the following detailed description and accompanying drawings wherein:

FIG. 1 comprises a block diagram of a contact input circuit according to various embodiments of the present invention;

FIG. 2 comprises a circuit diagram of a contact input circuit according to various embodiments of the present invention;

FIG. 3 comprises a plot of inverse power dissipation versus input voltage according to various embodiments of the present invention;

FIG. 4 comprises a circuit diagram of a contact input circuit according to various embodiments of the present invention;

FIG. 5 comprises a circuit diagram of a contact input circuit according to various embodiments of the present invention;

FIG. 6A and FIG. 6B comprise circuit diagrams of a contact input circuit according to various embodiments of the present invention;

FIG. 7 comprises a plot of the inverse of power dissipation according to various embodiments of the present invention;

FIG. 8 comprises a circuit diagram of a contact input circuit according to various embodiments of the present invention;

FIG. 9 comprises one example of a lookup table according to various embodiments of the present invention;

FIG. 10 comprises a block diagram of a contact input circuit according to various embodiments of the present invention; and

FIG. 11 comprises a block diagram of a contact input circuit according to various embodiments of the present invention.

Skilled artisans will appreciate that elements in the figures are illustrated for simplicity and clarity. It will further be appreciated that certain actions and/or steps may be described or depicted in a particular order of occurrence while those skilled in the art will understand that such specificity with respect to sequence is not actually required. It will also be understood that the terms and expressions used herein have the ordinary meaning as is accorded to such terms and expressions with respect to their corresponding respective areas of inquiry and study except where specific meanings have otherwise been set forth herein.

### DETAILED DESCRIPTION OF THE INVENTION

The approaches described herein provide contact input circuits that are power efficient and which can handle a wide range of wetting voltage ranges (e.g., from approximately 15 Vdc to approximately 350 Vdc). In some aspects, the contact input circuit employs a voltage attenuator to accommodate the wide voltage range.

In other aspects, the present approaches provide a universal contact input circuits that can handle an entire wetting voltage range. To be efficient, the circuit automatically adjusts its impedance (with respect to the wetting voltage) to keep the circuit power dissipation almost constant throughout the wetting voltage range. Besides being able to handle a large wetting voltage range and detect the contact status (e.g., open or closed), the circuits described herein can monitor the wetting voltage.

In yet other aspects, the contact input circuits described herein maintain the dissipated power (within a range or around a certain value) by either changing the circuit impedance continuously or intermittently as the wetting voltage changes. In some aspects, the wetting voltage is sensed or measured either continuously or in discrete steps.

In some examples, a contact input circuit is used to detect the status of a remotely located relay contact or other types of switching devices. The wetting voltage applied to such a relay can be in the range of approximately 15 Vdc to approximately 220 Vdc; approximately 110 Vac/60 Hz; or approximately 230V/50 Hz. These ranges match customer choices of using wetting voltages of approximately 24 Vdc, 28V, 48 Vdc, 125 Vdc, 220 Vdc, 110 Vac/60 Hz or 230 Vac/50 Hz (to mention a few examples).

The circuits provided herein are cost effective to construct, provide efficient power dissipation over a wide range of operating voltages, and reduce circuit part count. In these respects, the circuit topologies described herein are loop powered (i.e., they do not use an external power source but instead use the sensed voltage as a power source). The topologies of a universal contact input circuit described herein use a low count of simple passive components. The dissipation is controlled either continuously or intermittently to improve the overall efficiency of the circuit. Increased reliability of the circuit is achieved compared to previous approaches. Additionally, a universal contact input circuit allows the accommodation of any last minute changes of customer specifications (of the wetting voltage) and allows, for example, a customer to conveniently stock spare parts.

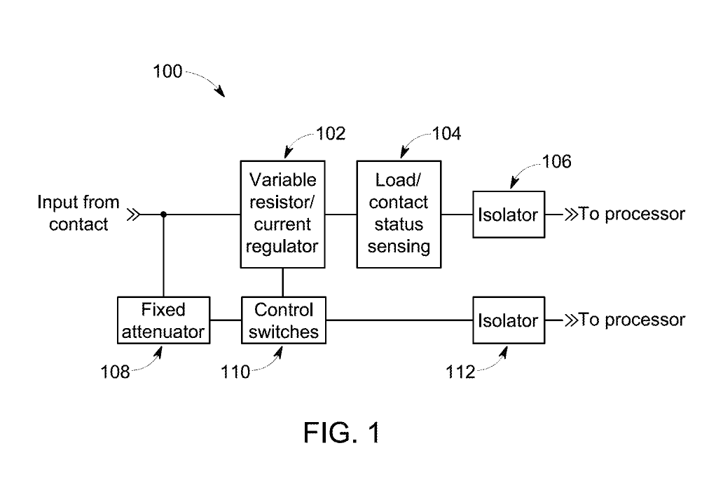

Referring now to the drawings and in particular to FIG. 1, a block diagram of a contact input circuit 100 is illustrated. The contact input circuit 100 receives an input voltage as may exist across the contacts of a switching device (e.g., a contact, not shown in FIG. 1). The input voltage is fed to a fixed attenuator 108 and then into a set of control switches 110. The control switches 110 are configured to control a variable current sink comprised of a variable resistor or variable current regulator 102.

In some examples, the control switches 110 may be configured to output a signal representative of a measured input voltage to a control system across an isolation barrier through a first isolator 112. Further, and also optionally, the resistor or variable current regulator 102 may be configured to determine the status of the switching device through a load and contact status sensing module 104, which also can communicate with the control system across the isolation barrier through a second isolator 106. So configured, a contact input circuit 100 can be provided to operate with a variety of input voltages and to vary an amount of wetting current across contacts of a switching device in accordance with, at least in part, the perceived input voltage. The first isolator 112 and the second isolator 106 communicate with a control system or processor (not shown). The control system may also include any combination of processing devices that execute programmed computer software and that are capable of analyzing information received from the contact input circuit 100.

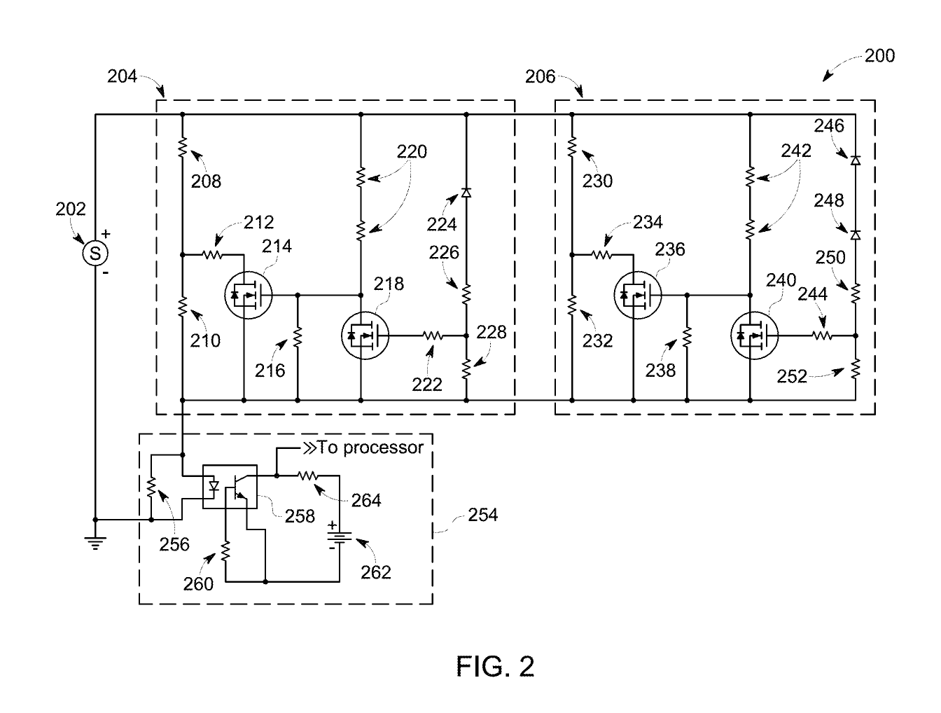

FIG. 2 illustrates a circuit diagram of a contact input circuit 200. The contact input circuit 200 includes a first switch/sink module 204 and a second switch/sink module 206 that are parallel to one another across the inputs to the contact input circuit 200. Each switch/sink module 204, 206 receives voltage from an input, for example, from one or more input contacts across a switching device (illustrated here as simulated voltage input 202). The received voltage may be provided by a power supply coupled to the switching device or from a device coupled to the switching device.

With respect to the first switch/sink module 204, the received voltage enters a resistive voltage divider consisting of resistors 208 and 210, with the signal between the resistors 208 and 210 being provided through resistor 212 to a drain of a transistor 214 (here shown as an N-channel FET, though other transistor types may be equally as suitable, including BJT transistors, CMOS transistors, and other FETs). The gate of transistor 214 is connected across one or more pull-up resistors 220 to the input voltage, as well as to a pull down resistors 216 (forming another resistor voltage divider circuit at the gate of the transistor 214). A second transistor 218 is provided such that its drain and source are in parallel with the pull down resistor 216 at the gate of the first transistor 214. The gate of the second transistor 218 is connected to at least one zener diode 224 that is configured to block current from flowing to the gate of the second transistor 218 until the input voltage achieves a particular minimum voltage to trigger the zener. For example, the zener diode may be approximately 50V, or more precisely 56V by one approach, though almost any value is possible and can be selected by a designer according to the desired behavior specifics of the circuit 200, including the desired granularity of the input voltage ranges.

As input voltage increases from 0V, the first transistor 214 will begin to sink current commensurate with the attenuated voltage at its gate input, thus creating power dissipation across the various resistors and a wetting current across the contacts of the switching device. As the input voltage increases beyond the voltage of the zener diode 224 (e.g., above approximately 50V), the current will begin to flow though the zener diode 224 and through voltage divider resistors 226 and 228, with the signal at the middle of voltage divider resistors 226 and 228 being fed to the gate of the second transistors 218 through a resistor 222. Eventually, the second transistor 218 will turn on and shunting the pull down resistor 216, thus creating a low input voltage to transistor 214 and stopping transistor 214 from sinking any current. Instead, a new current sink path is created through pull up resistors 220 and transistor 218. This new current sink path is of higher resistance than that through the first transistor 214 and resistors 208 and 212. Thus, as the first current sink path is removed by transistor 214 shutting off, the resistance of the entire current sink path increases, which reduces current therethrough, and reduces dissipated power.

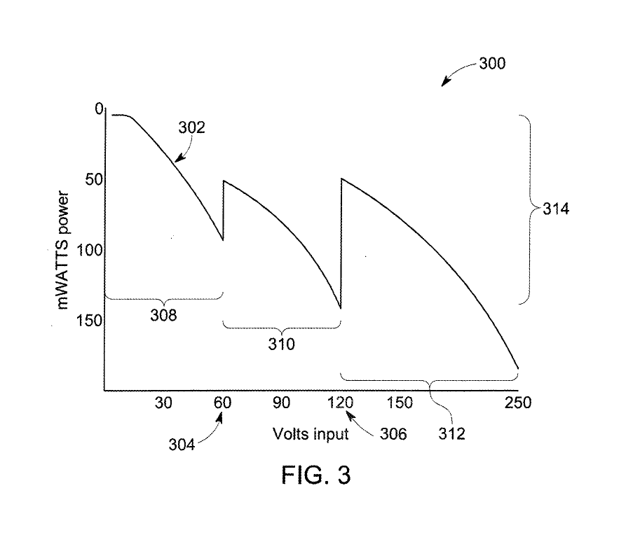

The second switch/sink module 206 can be provided that is nearly identical to the first switch/sink module 204 except for a few components. For example, the second module 206 will include the resistive voltage divider consisting of resistors 230 and 232, with the signal between the resistors 230 and 232 being provided through resistor 234 to a drain of a transistor 236. Like the first switch/sink module 204, the gate of transistor 236 is connected across one or more pull-up resistors 242 to the input voltage, as well as to a pull down resistor 238. A second transistor 240 is provided such that its drain and source are in parallel with the pull down resistor 238 at the gate of the first transistor 236. Like the first switch/sink module 204, the gate of the second transistor 240 is connected to at least one zener diode, and in this example, is connected to two zener diodes 246 and 248 in series. The zener diodes 246 and 248 in this example are simply the same value as zener diode 224, thus creating a voltage block that is double the voltage block of the zener diode 224. Other zener diode 246, 248 values are possible according to the desired behavior of the circuit 200, though it is preferred to select a combined value of zener diodes 246, 248 that exceed that of the first module so that a staggered switching may occur, some of the benefits of which will be described with respect to FIG. 3 below.

Like the first switch/sink module 204, as the input voltage exceeds the combined voltage of the zener diodes 246, 248, current will eventually flow through the diodes 246, 248 and through the divider resistors 250, 252 and through gate input resistor 244 so that the second transistor 240 turns on and shuts pull down resistor 238 to turn off first transistor 236. Again, as the resistance path through transistor 236 and resistors 230 and 234 was much less than the resistance path through transistor 240 and the pull up resistors 242, the overall resistance of the current sink path increases, thus lowering the current therethrough and lowering the overall power dissipation.

It may be beneficial to provide the pull up resistors 220, 242 as multiple resistors each in series as is shown (or in parallel, or with resistors beyond the two shown in FIG. 2) so that the power dissipated is spread across the multiple pull up resistors 220, 242 to prevent device failure. Further, it may also be beneficial to make the resistor 234 coupled to the drain of the first transistor 236 in the second module 206 greater than the sink resistor 212 coupled to the drain of the first transistor 214 of the first switch/sink module 204. This is because, when configured as described, the first transistor of the second module 206 will continue to sink current at higher input voltages than will the first transistor 214 of the first switch/sink module 204 due to the comparative voltages of the zener diodes 224 and 246, 248.

Further, though only two switch/sink modules 204, 206 are illustrated here, any number of switch/sink modules can be utilized, primarily dependant upon how tight of a power dissipation band 314 is desired (see FIG. 3) or how much granularity is desired on the input voltage.

Referring now to FIG. 3, an example plot 300 of the inverse of the power dissipation (on the y-axis) versus the input voltage (on the x-axis) is illustrated in accordance with an approach described with respect to FIG. 2. The curve 302 represents the power dissipation at each specified input voltage. With continuing reference to FIG. 2, during segment 308 of FIG. 3, transistors 214 and 236 will remain on. As the input voltage reaches and exceeds the voltage of the first zener diode 224 at voltage point 304, transistor 214 will turn off and transistor 218 will turn on. This increases the overall resistance of the current sink path, which reduces the current therethrough, which lowers the power dissipation, as is shown by the jump in power dissipation at point 304. During segment 310, transistors 218 and 236 will continue to sink current until the input voltage rises above the value of the zener diodes 246, 248 of the second module 206 at point 306. At this point 306, transistor 236 will shut off and transistor 240 will turn on, again increasing the overall resistance and lowering the current and total power dissipation. So configured, the total power dissipation is kept roughly within a desired power dissipation band 314 as may be optimized for providing appropriate wetting current across the contacts of the switching device across a wide range of input voltages.

Returning to FIG. 2, a load and contact status sensing circuit 254 portion is described. The input voltage is fed across a sensing resistor 256, which creates a voltage that is fed in parallel to an optocoupler 258 across an isolation barrier. The light sensing transistor portion of the optocoupler 258 will sense light from the light emitting diode LED portion of the optocoupler 258, which will allow current to flow through its base and resistor 260. This creates a current on the output, which allows current from a control-side power source to flow through pull down resistor 264 to produce a low output signal representative of current flow on the contact inputs. This signal can then be fed to a processing device for processing thereof.

Further, it is noteworthy that, as configured, the contact input circuit 200 is operated from power supplied across the input terminals to the contact input circuit 200, which eliminates the need for additional power sources or other external components to power the circuit. This has the effect of reducing implementation cost of the contact input circuit 200, as well as improving its compatibility with existing installations and/or new installations using varying control systems.

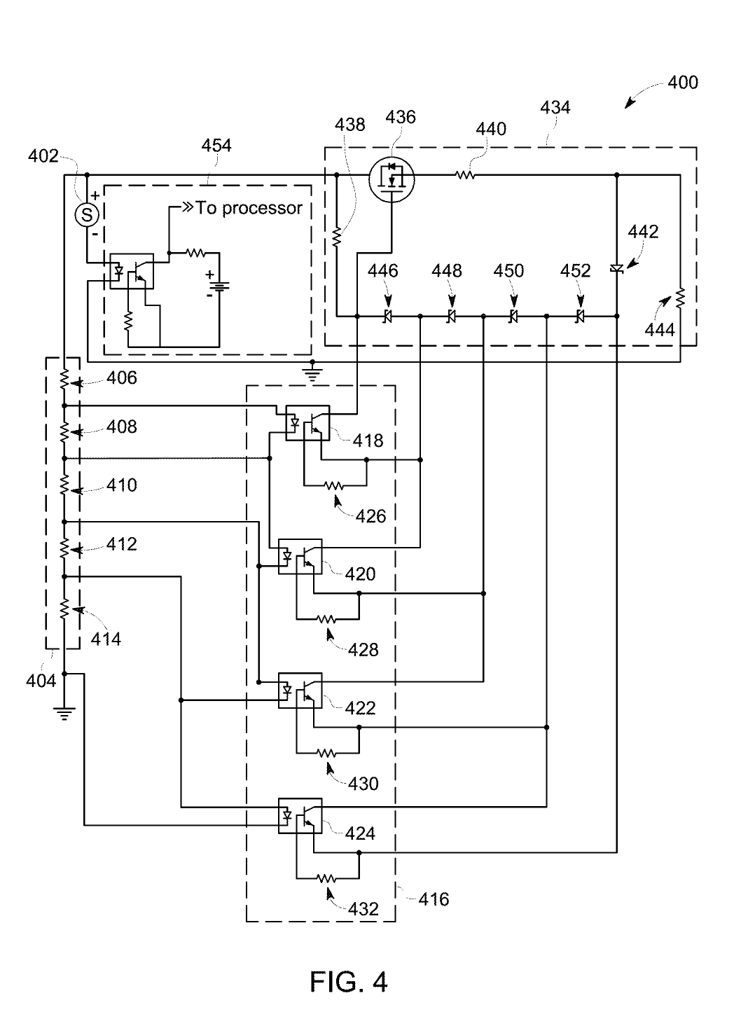

Turning now to FIG. 4, another example of a contact input circuit 400 is illustrated. Like with FIG. 2, input voltage is simulated for illustration purpose by voltage source 402. The voltage input is fed across a voltage divider 404 consisting of resistors 406, 408, 410, 412, and 414, which may correspond to the fixed attenuator 108 illustrated in FIG. 1. A set of optocouplers 418, 420, 422, 424 and corresponding base resistors 426, 428, 430, 432 comprise the control switches 110 of FIG. 1, with the resistor or variable current regulator 102 of FIG. 1 being shown at 434. A representative load across the switching device is shown by resistor 444. A load and contact status sensing circuit 454 is provided to sense a load across a load resistor 403 as was described with respect to the load and contact status sensing circuit 254 of FIG. 2.

The current regulator 434 includes a transistor 436 (shown here as a N channel FET, though other transistor types may be suitable) with its drain coupled to the input voltage and its source coupled to a load resistor 440, which is in series with load resistor 444, which returns to ground. The gate of the transistor 436 is coupled to a series of zener diodes 446, 448, 450, 452, 442 that establish the voltage at the gate. Pull up resistor 438 is coupled between the voltage input and the gate.

The input of each optocoupler 418, 420, 422, 424 is placed across one of the voltage divider resistors 408, 410, 412, 414, for example, optocoupler 418 is connected across resistor 408, optocoupler 420 is connected across resistor 410, optocoupler 422 is connected across resistor 412, and optocoupler 424 is connected across resistor 414. Each optocoupler output is placed in parallel with one of the zener diodes 446, 448, 450, 452. For example, the output of optocoupler 418 is in parallel with zener diode 446, the output of optocoupler 420 is in parallel with zener diode 448, the output of optocoupler 422 is in parallel with zener diode 450, and the output of optocoupler 424 is in parallel with zener diode 452.

The values of the resistors 406, 408, 410, 412, 414 are selected so that, in operation, as the input voltage increases, the optocouplers 418, 420, 422, 424 will be activated one by one across the allowable input voltage span (for example, evenly spaced between 0 and 500V). As each optocoupler is activated, the output will shunt its respective zener diode. Thus, as the input voltage increases, more optocouplers become active, thus shunting more zener diodes, thus lowering the drive voltage at the gate of the transistor 436. As the gate drive voltage is lowered, the current through the transistor 436 drops, thus reducing the wetting current and reducing the power dissipated. The result is a stepped power dissipation curve similar to was shown in FIG. 3 that keeps the power dissipation within an approximate band 314 over the entire input voltage range.

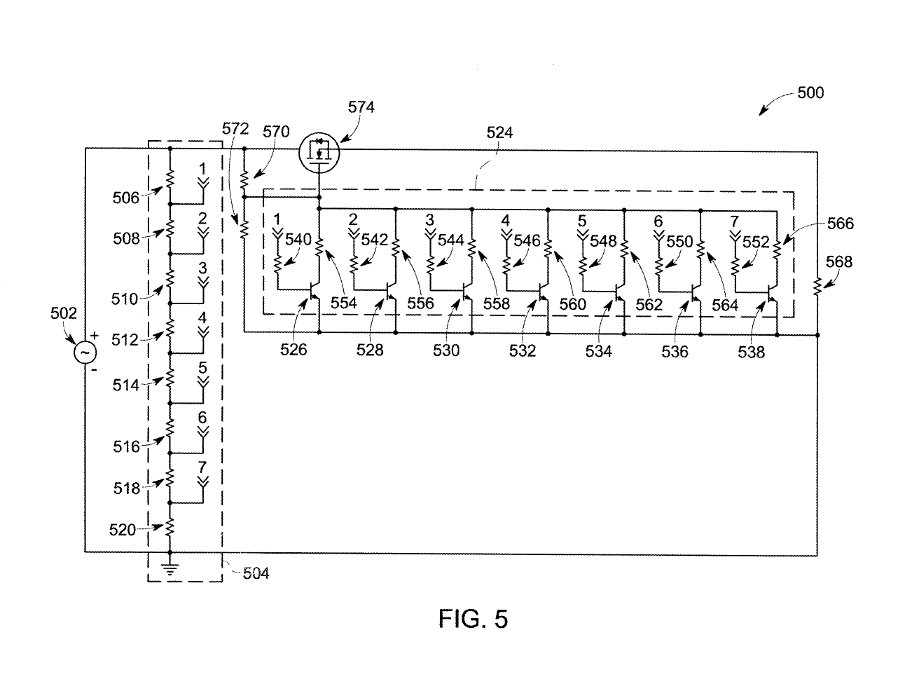

Referring now to FIG. 5, another example of a contact input circuit 500 is described. The contact input circuit 500 shows a representative input voltage 502 fed across a voltage divider 504 consisting of resistors 506, 508, 510, 512, 514, 516, 518, and 520. The nodes between each resistor of the voltage divider 504 are each fed into the base of individual transistors through individual input resistors in the switching circuit 524. For example, the node between resistor 506 and 508 is coupled to the base of transistor 526 through resistor 540; the node between resistor 508 and 510 is coupled to the base of transistor 528 through resistor 542; the node between resistor 510 and 512 is coupled to the base of transistor 530 through resistor 544; the node between resistor 512 and 514 is coupled to the base of transistor 532 through resistor 546; the node between resistor 514 and 516 is coupled to the base of transistor 534 through resistor 548; the node between resistor 516 and 518 is coupled to the base of transistor 536 through resistor 550; and the node between resistor 518 and 520 is coupled to the base of transistor 538 through resistor 552.

Each transistor is coupled to the gate of a current sink transistor 574 (here shown as an N channel FET, though other transistors may be suitable) through load resistors 554, 556, 558, 560, 562, 564, and 566. The gate of the current sink transistor 574 is also coupled to a voltage divider circuit comprised of a pull up resistor 570 and a pull down resistor 572. Each transistor and load resistor combination is in parallel with the pull down resistor 572 coupled between the gate of the current sink transistor 574 and ground. The drain of the current sink transistor 574 is coupled to the input voltage with its source coupled to a load resistor 568 representative of a load across the contact inputs.

The values of the resistors 506, 508, 510, 512, 514, 516, 518, and 520 of the voltage divider 504 are selected so that, in operation, as the input voltage increases, each transistor 526, 528, 530, 532, 534, 536, 538 will turn on one-by-one across the allowable input voltage span (for example, evenly spaced between 0 and 500V). For example, the value of resistor 508 may be the highest while the value of resistor 518 may be the lowest (with resistor 520 provided as a minimum basis resistance to trigger the last transistor in the series and resistor 506 being the largest and acting as an attenuating resistor) so that as voltage increases, the voltage at the top of resistor 508 will be the first to activate a transistor (i.e., transistor 526) and the voltage at the top of resistor 520 will be the last to activate a transistor (i.e., transistor 538). As each transistor is activated, current begins to flow through each transistor 526, 528, 530, 532, 534, 536, 538 and its respective load resistor 554, 556, 558, 560, 562, 564, 566.

As the input voltage increases from 0V, it will eventually reach a level through the voltage divider resistors 570 and 572 above the threshold of the current sink transistor 574, which will then allow current to flow therethrough in relation to the gate voltage. With no transistors of the switching circuit 524 on, the resistance to the gate of the current sink transistor 574 will be at its highest, and thus its voltage will be at the highest as well, which allows more current to flow. As the input voltage increases, eventually transistor 526 will turn on, allowing current to flow through resistor 554. The resistance of resistor 554 in parallel with the pull down resistor 572 lowers the total resistance seen at the gate of the current sink transistor 574, which resultantly lowers its current throughput, and lowers the respective power dissipation. As the voltage continues to rise, the other transistors will also turn on one-by-one and their respective load resistors will lower the gate resistance, thus lowering the gate voltage, which lowers the current and the power dissipation. The values of the load resistors 554, 556, 558, 560, 562, 564, 566 may be selected, by one approach, to be continuously decreasing (i.e., load resistor 554 may have a higher value than load resistor 566) so that the current output is tuned according to the input voltage to keep the power dissipation from the wetting current within an approximate band or range across the entire input voltage range.

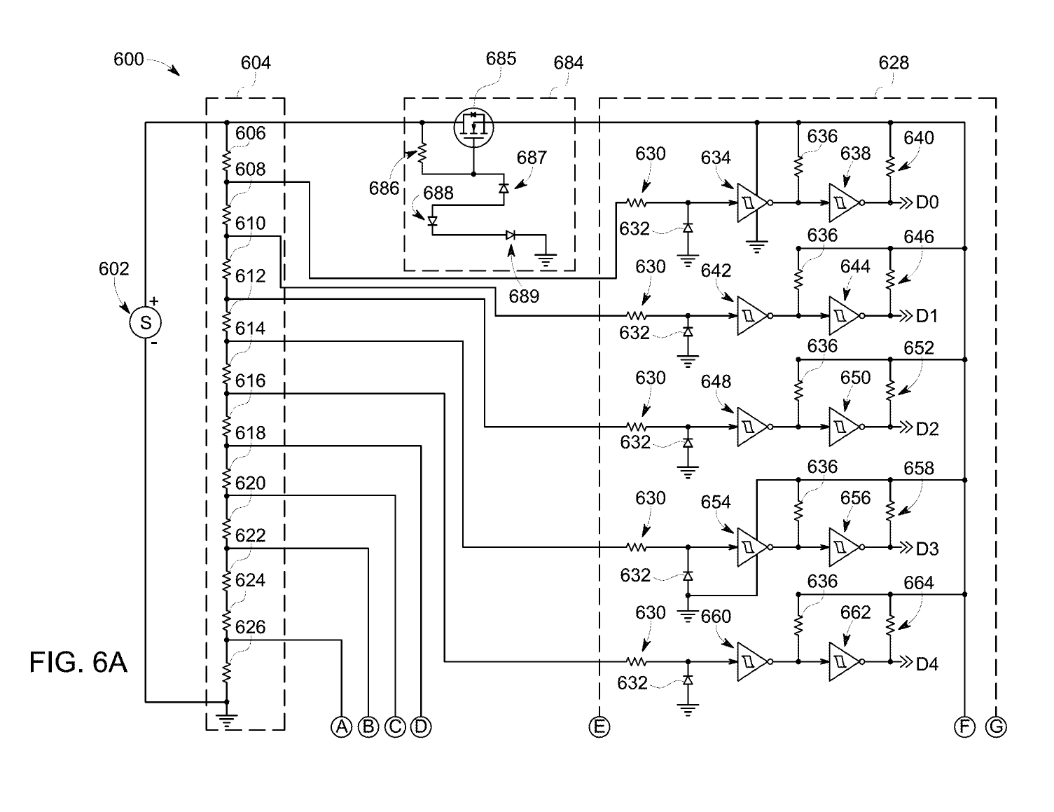

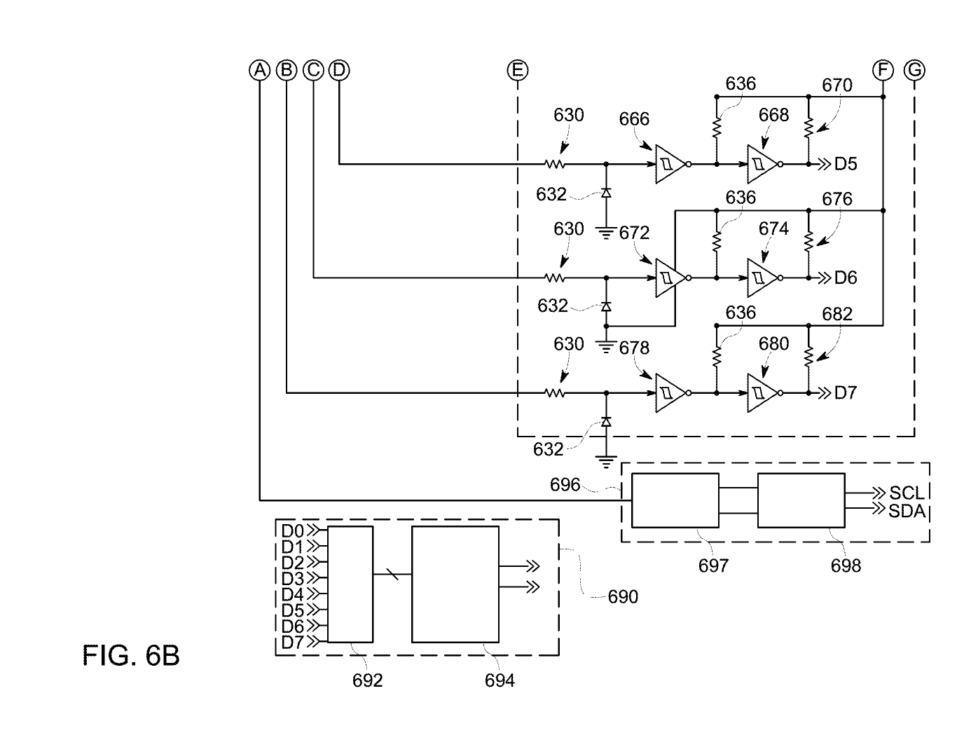

Referring now to FIG. 6A and FIG. 6B, yet another example of a contact input circuit is described. The example contact input circuit 600 includes a representative input voltage 602 fed across a voltage divider 604 consisting of resistors 606, 608, 610, 612, 614, 616, 618, 620, 622, 624, and 626. The nodes between each resistor of the voltage divider 604 are each fed into the input of an Open Collector Schmidt inverter (herein after referred to as Schmidt inverter for brevity) of the switching circuit 628 through a resistor 630 and across a clamping diode 632. For example, the node between resistor 606 and 608 is coupled to the input of Schmidt inverter 634; the node between resistor 608 and 610 is coupled to the input of Schmidt inverter 642; the node between resistor 610 and 612 is coupled to the input of Schmidt inverter 648; the node between resistor 612 and 614 is coupled to the input of Schmidt inverter 654; the node between resistor 614 and 616 is coupled to the input of Schmidt inverter 660; the node between resistor 616 and 618 is coupled to the input of Schmidt inverter 666; the node between resistor 618 and 620 is coupled to the input of Schmidt inverter 672, and the node between resistor 620 and 622 is coupled to the input of Schmidt inverter 678. The output of each Schmidt inverter 634, 642, 648, 654, 660, 666, 672, 678 is coupled to a pull up resistor 636 and the input of a second Schmidt inverter. For example, the output of Schmidt inverter 634 is coupled to the input of Schmidt inverter 638; the output of Schmidt inverter 642 is coupled to the input of Schmidt inverter 644; the output of Schmidt inverter 648 is coupled to the input of Schmidt inverter 650; the output of Schmidt inverter 654 is coupled to the input of Schmidt inverter 656; the output of Schmidt inverter 660 is coupled to the input of Schmidt inverter 662; the output of Schmidt inverter 666 is coupled to the input of Schmidt inverter 668; the output of Schmidt inverter 672 is coupled to the input of Schmidt inverter 674; and the output of Schmidt inverter 678 is coupled to the input of Schmidt inverter 680.

Each of the second Schmidt inverters is coupled to a resistor that is tied to the source of a current sink transistor 685. For example Schmidt inverter 638 is coupled to resistor 640; Schmidt inverter 644 is coupled to resistor 646; Schmidt inverter 650 is coupled to resistor 652; Schmidt inverter 656 is coupled to resistor 658; Schmidt inverter 662 is coupled to resistor 664; Schmidt inverter 668 is coupled to resistor 670; Schmidt inverter 674 is coupled to resistor 676; and Schmidt inverter 680 is coupled to resistor 682. These resistors are in parallel between the source of the current sink transistor and the Schmidt inverters to form a collective current sink load resistance.

A current regulator circuit 684 is provided, including current sink transistor 685 (shown here as an N channel FET, though other transistor types may be suitable) with its drain coupled to the input voltage. The gate of the current sink transistor 685 is coupled to a pull up resistor 686 and to a zener diode 687 as well as diodes 688 and 689. By this, the voltage at gate of the current sink transistor 685 will be set to the value of the zener diode 687 (here set to an example value of approximately 7.5V, though other values are possible) plus the diode drop voltage of the other optional diodes 688 and 689. The source of the current sink transistor 685 is coupled to the collective current sink load resistance formed by the set of resistors 640, 646, 652, 658, 664, 670, 676, and 682 in parallel.

The values of the resistors of the voltage divider 604 are selected so that, in operation, as the input voltage increases, a voltage on the input of each first Schmidt inverter will rise above the threshold voltage of the first Schmidt inverter causing its output to go low, thus causing the output of the coupled second Schmidt inverter to go high. For example, as the voltage at the top of resistor 608 exceeds the threshold input voltage for Schmidt inverter 634, the Schmidt inverter 634 output will go low, causing the second Schmidt inverter 638 to output a high signal. This process will continue itself with each respective Schmidt trigger set as the input voltage increases.

Prior to the voltage at each resistor of the voltage divider 604 exceeding the respective Schmidt inverter voltage, the output of each second Schmidt inverter 638, 644, 650, 656, 662, 668, 674, 680 will remain tied to ground. Thus, each load resistor 640, 646, 652, 658, 646, 670, 676, 682 will be tied in parallel between the source of the current sink transistor 685 and ground, which decreases the collective source resistance. With a lowered source resistance, the current sink transistor 685 will sink more current (as compared to a higher source resistance) to raise the voltage its source. In order to sink the necessary current provided through current sink transistor 685, the Schmidt inverters 638, 644, 650, 656, 662, 668, 674, 680 may be, by one example, open-collector Schmidt inverters. As the input voltage rises, more Schmidt inverters will go from lo to high, thus removing their respective load resistors from the collective parallel source resistance and effectively increasing the resistance seen by the source. As this resistance increases in steps (as the input voltage increases), the current sink transistor 685 will have to sink less current to keep its source voltage up, which reduces the wetting current and keeps the dissipated power within a band.

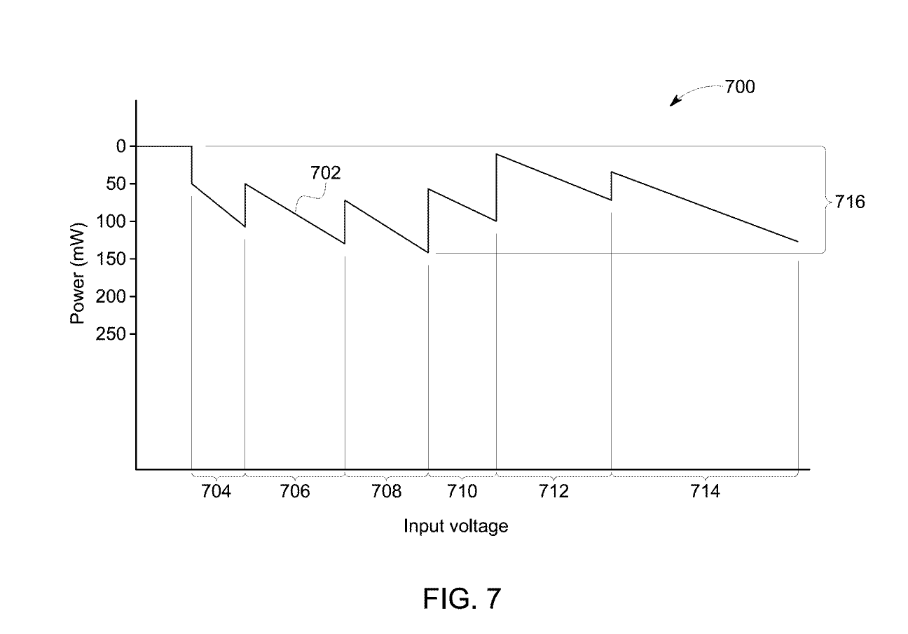

Referring now to FIG. 7, an example plot 700 of the inverse of the power dissipation (on the y-axis) versus the input voltage (on the x-axis) is illustrated in accordance with the approach described with respect to FIG. 6A and FIG. 6B. Similar to the example plot 300 of FIG. 3, FIG. 7 shows curve 702 represents the power dissipation at each specified input voltage. Each input voltage segment or range 704, 706, 708, 710, 712, and 714 refers to an input voltage range between the activation of the various Schmidt inverter pairs. So configured, as the input voltage increases, more Schmidt inverter pairs are activated, thus lowering the sink current resultantly keeping power dissipation within an approximate ideal power dissipation range shown by band 716.

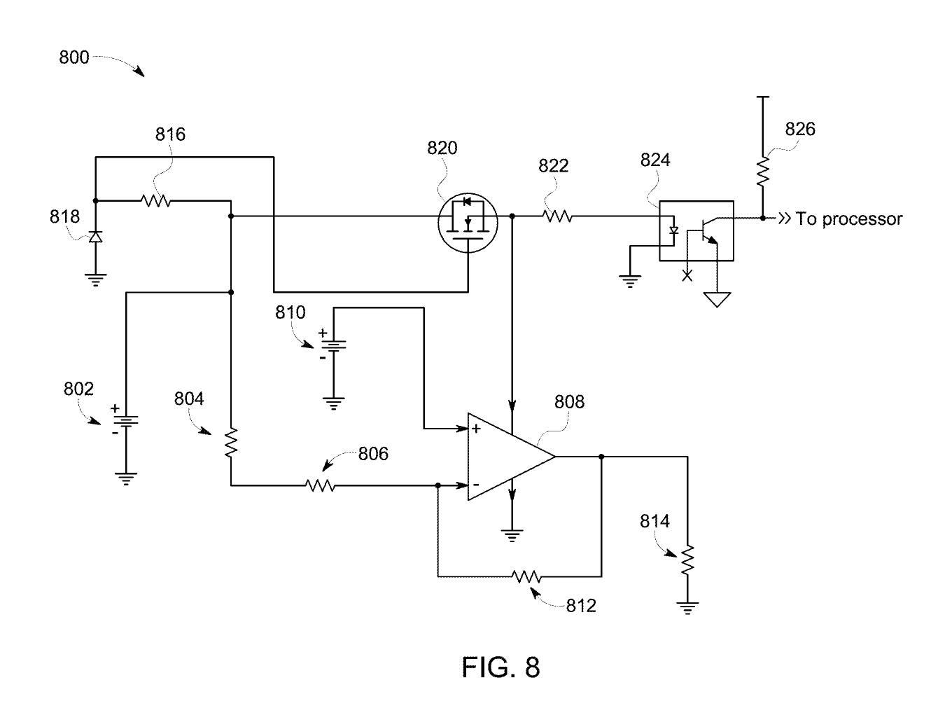

Referring now to FIG. 8, a circuit diagram of a contact input circuit 800 is described. A voltage source 802 representative of the input voltage across the input to the contact input circuit 800 is shown. The input voltage is fed to a drain of a transistor 820 (although an N channel FET is illustrated, other various transitory types may be appropriate). The voltage is fed through resistor 816 and across clamp diode 818 to the gate of the transistor 820. As the input voltage exceeds about 10V, a voltage at the source of the transistor 820 will remain approximately 6-8V and serves as a power supply for the contact input circuit 800. The power is fed through a resistor 822 into an optocoupler, which transmits the signal across an isolation barrier to an output served by a pull up resistor 826. This output can then be fed to a processing device to provide the status of the contacts (i.e., closed, open, powered, and so forth).

The input voltage is also fed to an inverting input of an op amp 808 through resistors 804 and 806. The non-inverting input of the op amp 808 receives a reference voltage 810. A feedback resistor 812 is provided between the output of the op amp 808 and the inverting input and establishes a gain (in comparison to the input resistors 804 and 806) for the op amp 808 to amplify the difference between the attenuated input voltage signal and the reference voltage 810. The op amp 808 receives supply power from the source of the transistor 820, as described above. Thus, because the op amp 808 inverts the difference between the input voltage signal and the reference voltage 810, as the input voltage increases, the output voltage of the op amp 808 will reduce. The resistor 814 represents the resistive load of a current sensing module. As the voltage across the resistor 814 decreases, the current also decreases. Thus, as the input voltage increases, the output wetting current decreases. Thus, linear control over the power dissipation is provided as compared to the stepped control described above.

Returning again to FIG. 6A and FIG. 6B, other aspects of the contact input circuit 600 are described. The Schmidt inverters are configured to change state as the input voltage increases. This state information can be provided to a processing device such that the processing device can know the present input voltage range. With brief reference to FIG. 7, or example, the processing device can determine if the input voltage is in range 704, 706, 708, 710, 712, or 714. This is particularly useful when an exact input voltage is not required but where knowledge of an approximate range would be useful for the processing device.

Returning again to FIG. 6A and FIG. 6B, two separate approaches are illustrated to provide the range data to a processing device. The first approach 696 involves the use of a serial analog-to-digital converter (ADC) 697 that may receive an attenuated voltage, for example, across resistor 626. The digitized voltage value can then transmitted serially through an isolator 698 across an isolation barrier (e.g., with an optocoupler) for use by a processing device.

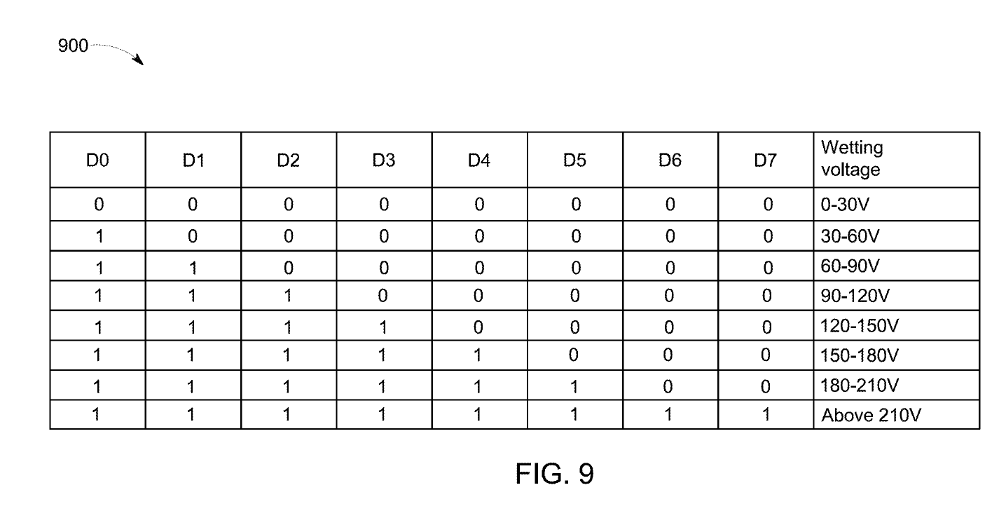

By another approach, 690, the outputs of the Schmidt inverters 638, 644, 650, 656, 662, 668, 674, 680 are each fed into one input of a serializer 692 which can then be fed into an isolator 694 for transmission across an isolation barrier for use by the processing device. Referring to FIG. 9, an example lookup table is illustrated that may be utilized by a processing device to convert the received data in this second approach 690 to voltage range information according to at least one approach.

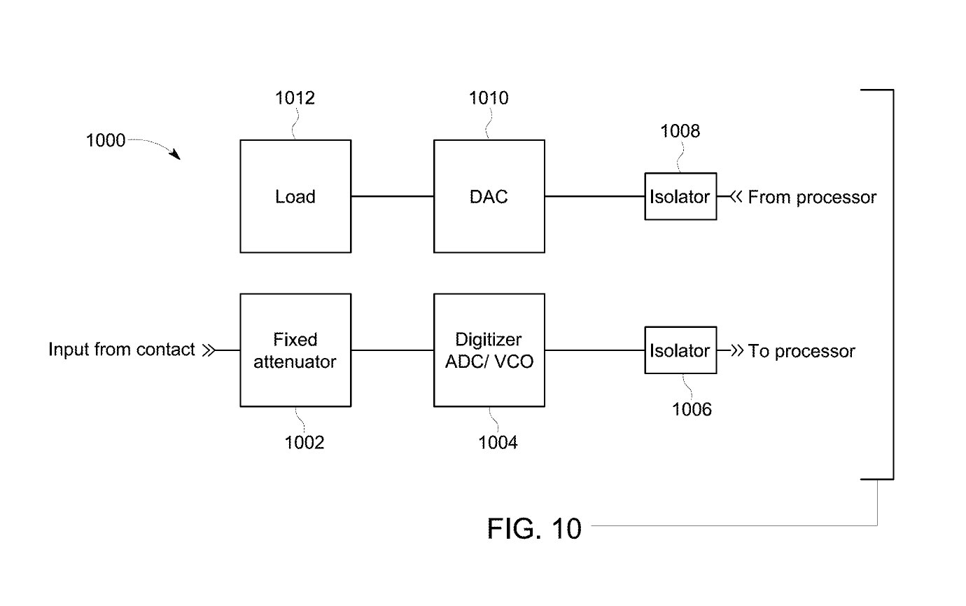

Referring next to FIG. 10, another example of a contact input circuit 1000 is described. The contact input circuit 1000 includes a fixed attenuator 1002 that receives the input from the input contacts. The attenuator 1002 acts as a voltage sensing block and feeds an attenuated version of the input voltage to an analog to digital converter (ADC) or voltage controlled oscillator 1004. The ADC/VCO 1004 sends a digitized signal through a first isolator 1006 (such as an optocoupler) across an isolation boundary to a processing device for processing thereof. Based on known transform functions or tables, the processing device will know the present input voltage and can decide an appropriate wetting current.

After deciding the appropriate wetting current, the processing device then sends a digital signal representative of the selected wetting current back across the isolation boundary through a second isolator 1008 to a digital-to-analog converter (DAC) 1010. The DAC then converts the digital signal to an analog output. The variability of the analog output then can be used to vary a wetting current provided on or by load 1012, as has been described above. The first isolator 1006 and the second isolator 1008 communicate with a control system or processor (not shown). The control system may also include any combination of processing devices that execute programmed computer software and that are capable of analyzing information received from the contact input circuit 1000.

Accordingly, by this approach, the contact input circuit is capable of operating with a wide range of input voltages while providing a processing device a relatively precise real-time measurement of the input voltage. The processing device can then utilize this information to control a wetting current as well as make other decisions or take other actions with respect to the circuit 1000.

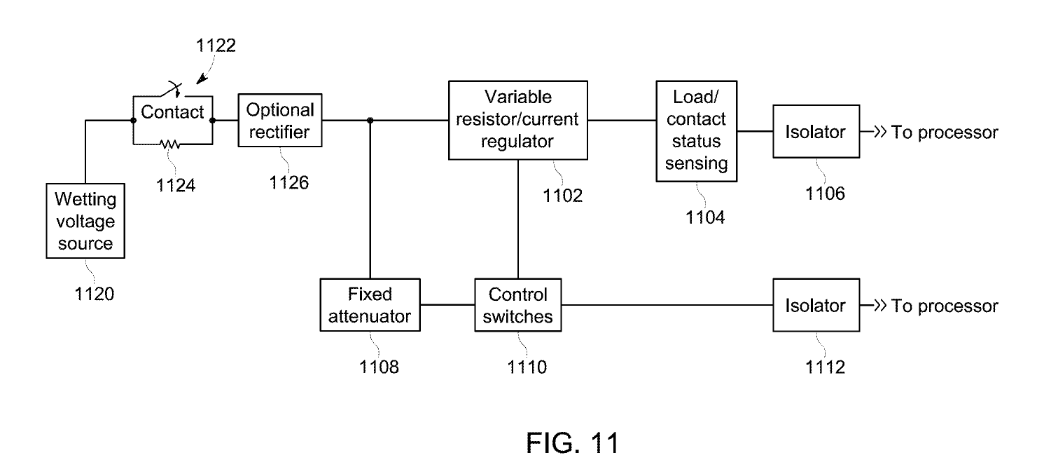

Referring now to FIG. 11, another example of a contact input circuit 1100 is described. The contact input circuit 1100 is similar to the contact input circuit of FIG. 1 and like numbered elements operate in the same way. In this respect, the contact input circuit includes a fixed attenuator 1108, a set of control switches 1110, a variable resistor or variable current regulator 1102, a load and contact status sensing module 104, a first isolator 1112, a second isolator 1106. In contrast to the example of FIG. 1, the circuit of FIG. 11 includes a switching device 1122 (e.g., a contact), a resistor 1124 that is connected electrically in parallel to the switching device 1122, and an optional rectifier 1126. A wetting voltage source 1120 is connected to the switching device 1122/resistor 1124. The optional rectifier 1126 converts and AC voltage to a DC voltage. The resistor 1124 is close to the switching device in the field and allows the detection of an open field wire condition. By “open field wire” condition, it is meant a break in either of the two wires that connect the customer terminal block and the switching device (e.g., contact) in the field (e.g., remote location to the contact input circuit 1100).

It will be appreciated that the various examples described herein use various components (e.g., resistors and capacitors) that have certain values. Some of these values may be shown in the figures. If not shown, these values will be understood or are easily obtainable by those skilled in the art and, consequently, are not mentioned here.

It will be appreciated by those skilled in the art that modifications to the foregoing embodiments may be made in various aspects. Other variations clearly would also work, and are within the scope and spirit of the invention. The present invention is set forth with particularity in the appended claims. It is deemed that the spirit and scope of that invention encompasses such modifications and alterations to the embodiments herein as would be apparent to one of ordinary skill in the art and familiar with the teachings of the present application.

1. A method of operating a contact input circuit, the method comprising:
at the contact input circuit:
sensing a voltage at a switching device, the voltage associated with a status of the switching device;
operating the contact input circuit according to the sensed voltage regardless of a value of the sensed voltage; and
maintaining a power usage of the contact input circuit to be within a predetermined range of power consumption values regardless of the value of the sensed voltage.

2. The method of claim 1, further comprising monitoring the voltage of the switching device.

3. The method of claim 2, wherein the monitoring determines a range of voltage values.

4. The method of claim 2, wherein the monitoring is performed continuously.

5. The method of claim 1, wherein the operating comprises converting the sensed voltage to a useable voltage regardless of the value and a type of the sensed voltage.

6. The method of claim 5, wherein the type of sensed voltage is a type selected from the group consisting of a direct current (DC) voltage and an alternating current (AC) voltage.

7. The method of claim 1 wherein the status comprise an open status or a closed status.

8. The method of claim 1 further comprising continuously monitoring the wetting voltage of the switching device and wherein the status comprises an open contact status, a closed contact status, or an open field wire status.

9. A contact input circuit, comprising:
a fixed attenuator sensing circuit that is configured to sense a voltage at a switching device, the voltage associated with a status of the switching device;
a control circuit, the control circuit coupled to the fixed attenuator sensing circuit, the control circuit configured to operate the contact input circuit according to the sensed voltage regardless of a value of the sensed voltage and maintain a power usage of the contact input circuit to be within a predetermined range of power consumption values regardless of the value of the sensed voltage.

10. The apparatus of claim 9, wherein the control circuit is configured to monitor the voltage of the switching device.

11. The apparatus of claim 10, wherein the control circuit determines a range of voltage values.

12. The apparatus of claim 10, wherein the control circuit monitors continuously.

13. The apparatus of claim 9, wherein the sensed voltage is converted to a useable voltage regardless of the value and a type of the sensed voltage.

14. The apparatus of claim 13, wherein the type of sensed voltage is a type selected from the group consisting of a direct current (DC) voltage and an alternating current (AC) voltage.

15. The apparatus of claim 9, wherein the status comprise an open status or a closed status.

16. The apparatus of claim 9, wherein the control circuit is configured to continuously monitor the wetting voltage of the switching device and wherein the status comprises an open contact status, a closed contact status, or an open field wire status.
